(19) United States
(12) Patent Application Publication
(10) Pub. No.: US 2010/0213991 A1
(43) Pub. Date: Aug. 26, 2010

(54) DELAY-LOCKED LOOP CIRCUIT AND METHOD FOR SYNCHRONIZATION BY DELAY-LOCKED LOOP

(75) Inventor: Ryo FUKUDA, Yokohama-Shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/714,136

(22) Filed: Feb. 26, 2010

(30) Foreign Application Priority Data
Feb. 26, 2009 (JP) 2009-43813

(51) Int. Cl. H03B 19/00; H03L 7/06; H03L 7/00

(52) U.S. Cl. 327/117; 327/158; 327/142

(57) ABSTRACT

A delay-locked loop circuit has an adjustment period setting module configured to set a rough adjustment period and a fine adjustment period, a delay time adjustment module configured to increase or decrease a delay stage by a first unit or by a second unit based on a delay stages setting value to generate a second signal by delaying a first signal, a delay module configured to generate a third signal by delaying the second signal by a predetermined time, a phase comparator configured to detect a phase difference between the first signal and the third signal, and a delay controller configured to generate the delay stages setting value based on the phase difference in order to increase or decrease the number of delay stages by the first unit when the rough adjustment period is set and to increase or decrease the number of delay stages by the second unit when the fine adjustment period is set.

### CROSS REFERENCE TO RELATED APPLICATIONS

This application is based upon and claims the benefit of priority from the prior Japanese Patent Applications No. 2009-43813, filed on Feb. 26, 2009, the entire contents of which are incorporated herein by reference.

### BACKGROUND OF THE INVENTION

1. Field of the Invention

The invention relates to a delay-locked loop circuit and a method for synchronization by delay-locked loop, which adjust a phase of a clock.

2. Related Art

As performance of semiconductor devices improves, a high speed operation is required on a bus between chips. In particular, speed-up of the bus between a memory controller and a memory is remarkable in recent years. A delay-locked loop (DLL) circuit is necessary for speed-up. The DLL performs phase compensation for coinciding a phase of a clock used in the memory with that of a clock provided from the memory controller in a chip different from the memory.

Data read out from the memory is outputted from an output buffer to the memory controller in synchronization with a clock INTCK in the memory. The memory controller receives the data from the memory after a time Tout required for outputting the data. Therefore, the memory has to output the data in synchronization with a clock having a phase faster than that of a clock EXTCK used in the memory controller by a time Tout required for data output. That is, the phase of the clock INTCK used in the memory has to be faster than that of the clock EXTCK by the time Tout. In order to generate such a clock INTCK, the DLL is used. Therefore, the DLL is integrated in the memory.

Furthermore, the DLL can be also integrated in the memory controller. It is preferable that the memory controller receives the data from the memory at the timing when a margin of a setup/hold time is the largest. This timing indicates timing when the phase of the EXTCK synchronized with the data is shifted by 180 degree. Also in order to generate such a clock, the DLL is used.

Thus, the DLL is inevitable for memory bus which requires a high speed operation.

Non-patent Document 1 (“A 1.5V, 1.6 Gb/s/pin, 1 Gb DDR3 SDRAM with an Address Queuing Scheme and Bang-Bang Jitter Reduced DLL Scheme” Yang Ki Kim et al, 2007 VLSI Circuit Symposium Digest of Technical Papers pp. 182-183) discloses a unit delay stage number varying type of DLL having multiple unit delay circuits. The DLL generates an internal clock INTCK having a phase faster than that of the external clock EXTCK by a time Tout by adjusting the number of delay stages.

However, in a manner of searching the optimum number of delay stages by adjusting the number of delay stages one stage by one stage, the adjustment has to be repeated as many as the total number of delay stages of the unit delay circuits until a final clock INTCK is generated (locked-up). Therefore, there is a problem that it takes a considerable time to set the number of delay stages. Furthermore, in order to improve adjustment accuracy, the delay time of each unit delay circuit has to be shortened and the number of the unit delay circuits has to be increased. As a result, there is also a problem that the time required to be locked up further increases.

### SUMMARY

According to one aspect of the present invention, a delay-locked loop circuit comprising: an adjustment period setting module configured to set a rough adjustment period and a fine adjustment period; a delay time adjustment module configured to increase or decrease a delay stage by a first unit or by a second unit based on a delay stages setting value to generate a second signal by delaying a first signal; a delay module configured to generate a third signal by delaying the second signal by a predetermined time; a phase comparator configured to detect a phase difference between the first signal and the third signal; and a delay controller configured to generate the delay stages setting value based on the phase difference in order to increase or decrease the number of delay stages by the first unit when the rough adjustment period is set and to increase or decrease the number of delay stages by the second unit when the fine adjustment period is set.

According to the other aspect of the present invention, a delay-locked loop circuit comprising: an adjustment period setting module configured to set a rough adjustment period and a fine adjustment period; a delay time adjustment module configured to generate a second signal by delaying a first signal based on a delay stages setting value; a delay module configured to generate a third signal by delaying a second signal by a predetermined time; a phase comparator configured to detect a phase difference between the first signal and the third signal; and a delay controller configured to update the delay stages setting value with a first cycle when the rough adjustment period is set and with a second cycle which is longer than the first cycle when the fine adjustment period is set.

According to the other aspect of the present invention, a method for synchronization by delay-locked loop comprising: setting a rough adjustment period and a fine adjustment period; increasing or decreasing a delay stage by a first unit or by a second unit based on a delay stages setting value and to generate a second signal by delaying a first signal; generating a third signal by delaying the second signal for a predetermined time; detecting a phase difference between the first signal and the third signal; and generating the delay stages setting value based on the phase difference in order to increase or decrease the number of delay stages by the first unit when the rough adjustment period is set and to increase or decrease the number of delay stages by the second unit when the fine adjustment period is set.

### BRIEF DESCRIPTION OF THE DRAWINGS

FIG. 1 is a block diagram showing a schematic configuration of a DLL circuit 100 according to a first embodiment of the present invention.

FIG. 2 is a block diagram showing an example of an internal configuration of a j-th (j=0 to 255) unit delay circuit 3.

FIG. 3 is a block diagram showing an example of an internal configuration of a unit variable counter 9.

FIG. 4 is a block diagram showing an example of an internal configuration of each counter module 21.

FIG. 5 is a block diagram showing an example of an internal configuration of a count unit varying circuit 22.

FIG. 6 is a table showing an example of the output value (count value) of the unit variable counter 9 when the signal DLLFSDUR is high.

FIG. 7 is a phase diagram showing a relationship of the phase of a clock EXTCKX, an internal clock INTCK and a clock INTCKX as a basis for an external clock EXTCK.

FIG. 8 is a timing chart showing an example of the processing operation of the DLL 100.

FIG. 9 is a timing chart showing a state where the clock EXTCKX and the clock INTCKX are locked (stabilized).

FIG. 10 is a block diagram showing an example of an internal configuration of the unit variable counter 9a.

FIG. 11 is a table showing a relationship of an increase/decrease unit in the DLL 100 during a rough adjustment period, a period T1, a period T2 and a total period T.

FIG. 12 is a block diagram showing a schematic configuration of a DLL circuit 100a according to a fourth embodiment of the present invention.

FIG. 13 is a block diagram showing an example of an internal configuration of a divider-with-selector 18.

FIG. 14 is a timing chart showing an example of the processing operation of the DLL 100a.

### DETAILED DESCRIPTION OF THE INVENTION

Hereinafter, DLL circuits and methods for synchronization by DLL according to embodiments of the present invention will be explained with reference to accompanying drawings.

### First Embodiment

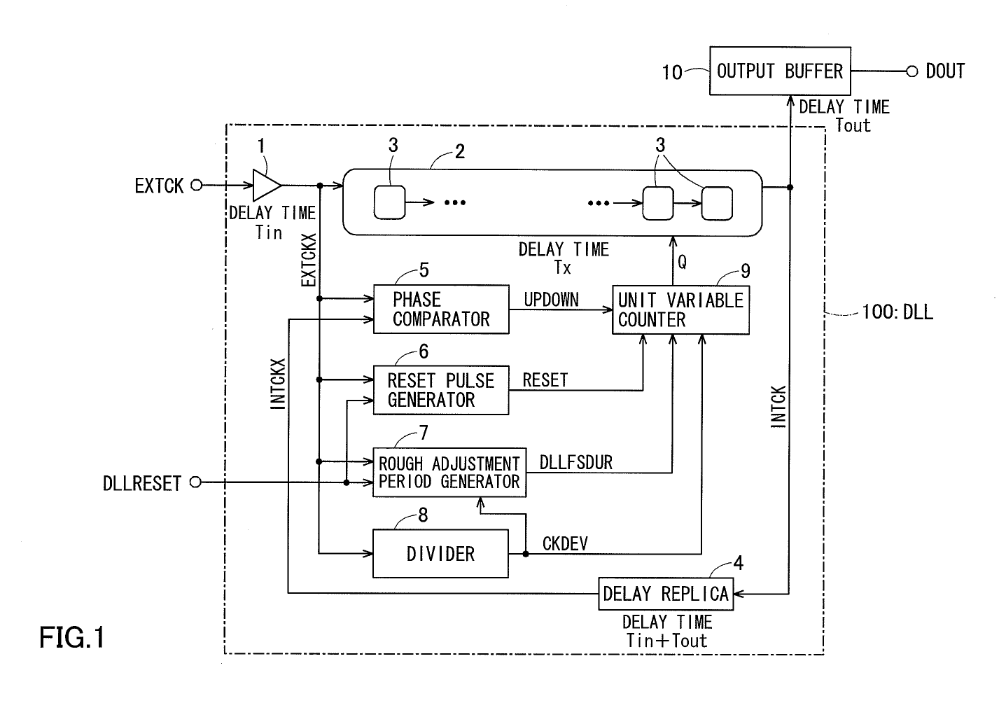

FIG. 1 is a block diagram showing a schematic configuration of a DLL circuit 100 according to a first embodiment of the present invention. The DLL 100 has an input receiver 1, a delay chain circuit (delay time adjustment module) 2, a delay replica (delay module) 4, a phase comparator 5, a reset pulse generator 6, a rough adjustment period generator (adjustment period setting module) 7, a divider 8, and a unit variable counter (delay controller) 9.

The DLL 100 of FIG. 1 adjusts a delay time Tx of the delay chain circuit 2 so that a phase of a clock EXTCKX coincides with that of a clock INTCKX and then to generate an internal clock INTCK having a phase faster than that of an external clock EXTCK by a delay time Tout. The operation principle will be explained in detail below.

For example, when the DLL 100 of FIG. 1 is integrated in a memory (not shown), the memory operates in synchronization with the internal clock INTCK. A memory controller (not shown) receives data from the memory through the output buffer 10 at the delay time Tout behind the internal clock INTCK.

The input receiver 1 of FIG. 1 receives the external clock EXTCK and buffers the external clock EXTCK to output a clock EXTCKX. Hereinafter, a delay time of the input receiver 1 will be defined as Tin.

The delay chain circuit 2 delays the clock EXTCKX (first signal) by the delay time Tx to generate the clock INTCK (second signal). The delay chain circuit 2 has a plurality of unit delay circuits 3 connected in series. The delay time Tx is adjustable according to the number of the unit delay circuits 3 to be used (hereinafter, referred to as the number of delay stages Q). The number of the unit delay circuits 3 to be used is adjusted by a count value (delay stages setting value) of the unit variable counter 9. The present embodiment shows an example where the delay chain circuit 2 can use “256” unit delay circuits 3 at the maximum, and the number of delay stages Q is expressed by a signal of “8” bits. Note that the number of the unit delay circuits 3 is not limited to this example.

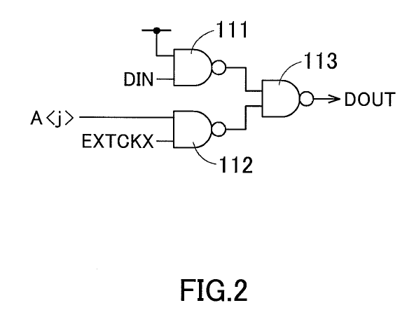

FIG. 2 is a block diagram showing an example of an internal configuration of the j-th (j=0 to 255) unit delay circuit 3. The unit delay circuit 3 has NAND circuits 111 to 113. An output DOUT of the j-th unit delay circuit 3 is connected to an input terminal DIN of the (j+1)-th unit delay circuit 3. The delay chain circuit 2 is obtained by connecting the “256” unit delay circuits 3 in series. Here a signal A<j> is a signal obtained by decoding the number of delay stages Q.

An example will be explained below where the delay chain circuit 2 delays the clock EXTCKX by “128” stages, that is, Q<0:7>=“00000001”. In this example, only the signal A<128> is high and the other signals A<k> (k≠128) are low. In this case, among the unit delay circuits 3 connected in series, only the clock EXTCKX in the 128th unit delay circuit 3 is effective. On the other hand, DIN, which is an output of the (k−1)-th unit delay circuit 3, is effective in the k-th unit delay circuits 3 except 128th unit delay circuit 3. As a result, the delay chain circuit 2 can generate the clock INTCK by delaying the clock EXTCKX by “128” stages.

The internal configuration of the unit delay circuit 3 of FIG. 2 is only an example, and the unit delay circuit 3 can be implemented by various circuits.

The delay replica 4 is a circuit for monitoring the delay time Tin of the input receiver 1 and the delay time Tout of the output buffer 10 described below and generates a clock INTCKX (third signal) by delaying the internal clock INTCK by a delay time (Tin+Tout).

The phase comparator 5 compares the phase of the clock EXTCKX with that of the clock INTCKX and generates a signal UPDOWN of “1” bit according to the phase difference to provide the signal UPDOWN to the unit variable counter 9. When the signal UPDOWN is low, it is expressed that the phase of the clock INTCKX is faster than that of the clock EXTCKX, while when the signal UPDOWN is high, it is expressed that the phase of the clock INTCKX is later than that of the clock EXTCKX.

The reset pulse generator 6 generates a reset pulse signal RESET in synchronization with a reset signal DLLRESET inputted from the outside to provide the reset pulse signal RESET to the unit variable counter 9.

The rough adjustment period generator 7 generates a rough adjustment period signal DLLFSDUR having a predetermined pulse width in synchronization with the reset signal DLLRESET to provide the rough adjustment period signal DLLFSDUR to the unit variable counter 9. When the rough adjustment period signal DLLFSDUR is high, a rough adjustment period is expressed, and when the signal DLLFSDUR is low, a fine adjustment period is expressed.

The divider 8 generates a divided clock CKDEV by frequency-dividing the clock EXTCKX to provide the divided clock CKDEV to the unit variable counter 9. The present embodiment shows an example where the divider 8 generates the divided clock CKDEV whose frequency is ¼ of that of the clock EXTCKX. However, it is not always necessary for the divider 8 to divide the frequency of the clock EXTCKX into ¼, and the divider 8 can divide the frequency of the clock EXTCKX into a frequency that a feedback loop of the DLL 100 can follow, as will be explained below.

The unit variable counter 9 sets the number of delay stages Q to be “128”, which is half the number of unit delay circuits 3 (hereinafter, referred to as initial number of delay stages) when the reset pulse signal RESET becomes high. That is, in the initial state, the number of delay stages Q is set to be an intermediate value. The unit variable counter 9 increases or decreases the number of delay stages Q in synchronization with the divided clock CKDEV when the reset pulse signal RESET becomes low.

The unit variable counter 9 increases a count value indicative of the number of delay stages Q when the signal UPDOWN is high and decreases the count value indicative of number of delay stages Q when the signal UPDOWN is low. It is one of the characteristic features that the unit of increasing or decreasing the number of delay stages Q (hereinafter, referred to as increase/decrease unit) during the rough adjustment period (when the signal DLLFSDUR is high) is different from that during the fine adjustment period (when the signal DLLFSDUR is low), which will be explained below. That is, in the present embodiment, an update unit of the count value of the unit variable counter 9 is switched according to the rough adjustment period or the fine adjustment period.

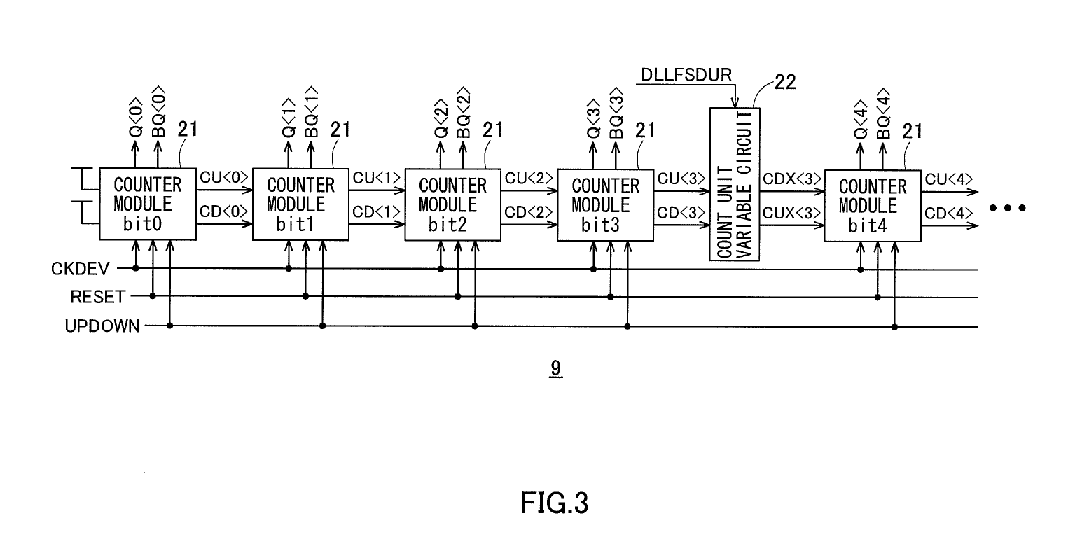

FIG. 3 is a block diagram showing an example of an internal configuration of the unit variable counter 9. The unit variable counter 9 has eight counter modules 21 connected in series and a count unit varying circuit 22. Each of the eight counter modules 21 corresponds to each of the bits of the count value of the unit variable counter 9. The left side of FIG. 3 corresponds to the lower bits, and the right side corresponds to the upper bits. The four counter modules 21 setting the lower four bits corresponds to a first counter, and the four counter modules 21 setting the upper four bits corresponds to a second counter.

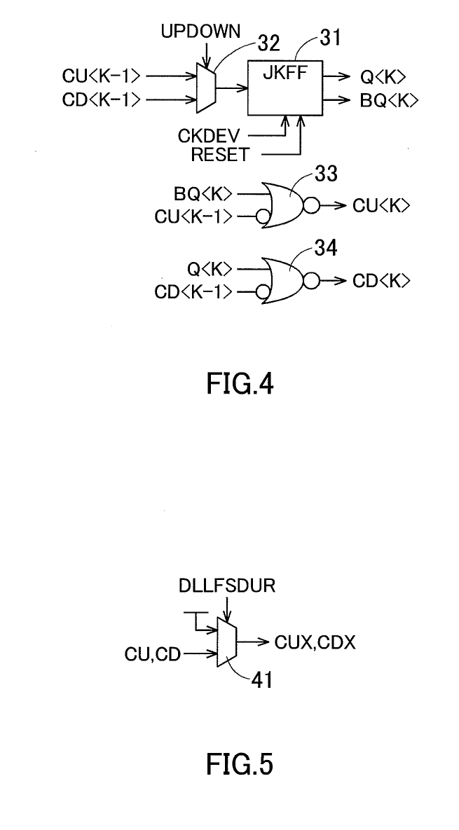

FIG. 4 is a block diagram showing an example of an internal configuration of each counter module 21. As shown in FIG. 4, the counter module 21 has a JK flip-flop 31, a multiplexer 32, logic gate circuits 33 and 34. The multiplexer 32 selects one of the two inputs according to the logic of the signal UPDOWN. As shown in FIG. 3, two high level input signals are inputted to the multiplexer 32 in the counter module 21 at initial stage, while two carry outputs CU and CD of each counter module 21 subsequent to the counter module 21 at initial stage are inputted to the multiplexers 32 in the counter modules 21 at the previous stage. The multiplexer 32 in each counter module 21 selects one of the carry output CU and CD according to the logic of the signal UPDOWN.

More specifically, the multiplexer 32 in the counter module 21 at k-th (k≧2) bit selects the carry output CU<k−1> of the neighboring counter module 21 of the lower bit side when the signal UPDOWN is high, and selects the carry output CD<k−1> when the signal UPDOWN is low. Then, receiving the CU<k−1> or CD<k−1>, the JK flip-flop 31 generates Q<k> and BQ<k>, which is an inversed signal of the Q<k>, according to the logic of the CU<k−1> or CD<k−1> in synchronization with the divided signal CKDEV. The logic gate circuit 33 generates the carry output CU<k> for the upper bit according to the logic of the BQ<k> and the CU<k−1>. The logic gate circuit 34 generates the carry output CD<k> for the upper bit according to the logic of the Q<k> and the CD<k−1>.

The count unit varying circuit 22 is inserted between the counter modules 21 at fourth and fifth bits. FIG. 5 is a block diagram showing an example of an internal configuration of the count unit varying circuit 22. As shown in FIG. 5, the count unit varying circuit 22 has a multiplexer 41. The multiplexer 41 selects the high level when the signal DLLFSDUR is high, and selects carry output CU<3> and CD<3> of the neighboring (fourth bit) counter module 21 of the lower bit side when the signal DLLSFDUR is low.

When the signal DLLFSDUR is low, the unit variable counter 9 of FIG. 3 operates as well as a normal up/down counter which increases or decreases the count value by “1”. Therefore, the unit variable counter 9 increases or decreases the number of delay stages Q by “1” in synchronization with the divided clock CKDEV. That is, the increase/decrease unit during the rough adjustment period is “1”.

On the other hand, when the signal DLLFSDUR is high, the unit variable counter 9 forcibly set the two input signals CUX<3> and CDX<3> of the counter modules 21 at the fifth bit from the lower bit side by the count unit varying circuit 22. Because of this, the counter modules 21 at the fifth or upper bits from the lower bit side performs a count operation separate from those of the counter modules 21 from the least significant bit (LSB) to the fourth bit. More specifically, in synchronization with the divided clock CKDEV, the counter modules 21 from the LSB to the fourth bit increase or decrease by “1”, and the counter modules 21 from the fifth bit to the most significant bit (MSB) from the lower bit side also increase or decrease by “1” in parallel. As a result, the count value increases or decreases by “17”. Therefore, the unit variable counter 9 increases or decreases the number of delay stages Q by “17”.

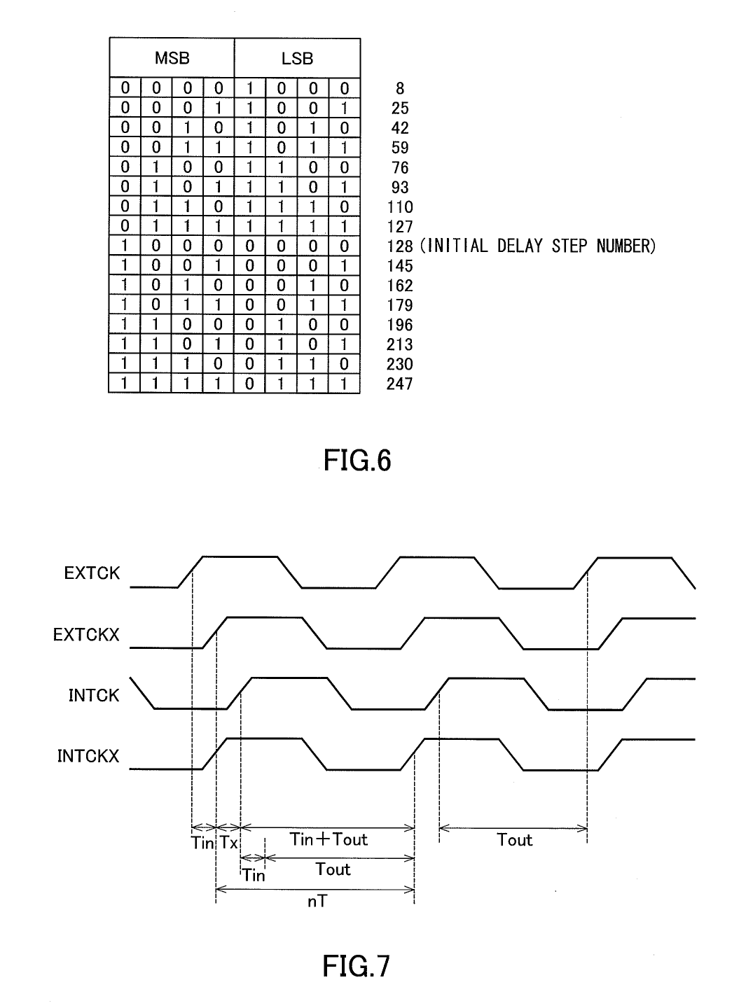

FIG. 6 is a table showing an example of the output value (count value) of the unit variable counter 9 when the signal DLLFSDUR is high. For simplification, FIG. 6 shows an example where eight counter modules 21 are connected in series, and a count up/down operation is performed from “128”, which is an initial setting value. As shown in FIG. 6, the counter modules 21 at the lower four bits (first counter) and those at the upper four bits (second counter) perform the count up/down operation separately. As a result, the difference between the count value in the case where count-down operation is performed only once from all “0” (128) of the lower four bits and the count value in the case where count-up operation is performed only once from all “1” (127) of the lower four bits is “1”, while the difference between the count values in the other cases is “17”. Therefore, the average of the increase/decrease unit (difference of the count values) is “16”.

Thus, with a simplified configuration obtained by inserting only one count unit varying circuit 22 shown in detail in FIG. 5 to the up/down counter of “8” bits in which eight counter modules 21 are connected in series, it is possible to implement the unit variable counter 9 where the increase/decrease unit of the count value during the rough adjustment period (first unit) is different form that during the fine adjustment period (second unit).

In FIG. 3, the average increase/decrease unit of the number of delay stages during the rough adjustment period is set to be “16”. However, the increase/decrease unit can be varied by changing the number of the counter modules 21 connected in the left side of the count unit varying circuit 22. For example, when there is only one counter module 21 in the left side of the count unit varying circuit 22, the increase/decrease unit during the rough adjustment period becomes “2”. This is the smallest increase/decrease unit. According to the present embodiment, an average of the increase/decrease unit of the number of delay stages Q during the rough adjustment period can be set to be “2^{k}” (k is a positive integer) which is equal to or more than “2”.

Here, the reason why the unit variable counter 9 increases or decreases the number of delay stages Q in synchronization not with the external clock EXTCK, but with the divided clock CKDEV whose frequency is ¼ of that of the external clock EXTCK is that the feedback loop of the DL 100, from when the phase of the clock INTKX is fixed by changing the number of delay stages Q, until the phase comparator 5 detects the phase difference, needs a time more than “3” clocks of the external clock EXTCK.

The DLL 100 of FIG. 1 is, for example, integrated in the memory. The memory adjusts the phase of the external clock EXTCK provided from outside by using the DLL 100 to generate the internal clock INTCK. In synchronization with the internal clock INTCK, the data stored in the memory is outputted through the output buffer 10 provided outside of the DLL 100 as data DOUT. Here, the delay time of the output buffer 10 is defined as Tout.

Next, the processing operation of the DLL 100 of FIG. 1 will be explained.

The DLL 100 of FIG. 1 adjusts the delay time Tx of the delay chain circuit 2 so that the phase of the clock EXTCKX obtained by buffering the external clock EXTCK by the input receiver 1 coincides with that of the clock INTCKX obtained by delaying the internal clock INTCK outputted from the delay chain circuit 2 by the delay replica 4. As a result, it is possible to generate the internal clock INTCK having the phase faster than that of the external clock EXTCK by the delay time Tout can be generated. This will be explained below.

FIG. 7 is a phase diagram showing a relationship of the phase of the clock EXTCKX, the internal clock INTCK and the clock INTCKX, which use the external clock EXTCK as a reference. Because the clock EXTCKX is outputted from the input receiver 1, the delay time thereof is Tin. Because the internal clock INTCK passes through the input receiver 1 and the delay chain circuit 2, the delay time thereof is Tin+Tx. Because the clock INTCKX passes through the input receiver 1, the delay chain circuit 2 and the delay replica 4, the delay time thereof is Tin+Tx+(Tin+Tout).

The phase difference between the clock EXTCKX (delay time Tin) and the clock INTCKX (delay time Tin+Tx+(Tin+Tout)) is Tx+Tin+Tout, which is a difference between the delay times of both clock. The DLL 100 adjusts the count value of the unit variable counter 9 so that the phase difference becomes an integral multiplication of the cycle T of the external clock EXTCK and the internal clock INTCK. In this case, the following equation (1) is established.

n*T=Tx+Tin+Tout (1)

Here, n is a positive integer. By modifying the equation (1), the following equation (2) is obtained.

Tin+Tx=n*T−Tout (2)

The value Tin+Tx in the left side of the equation (2) equals to the delay time of the internal clock INTCK. The value, as shown by the value in the right side of the equation (2), equals to the case of forwarding the phase by the delay time Tout. In such a manner, the DLL 100 generates the internal clock INTCK having the phase faster than that of the external clock EXTCK by the delay time Tout.

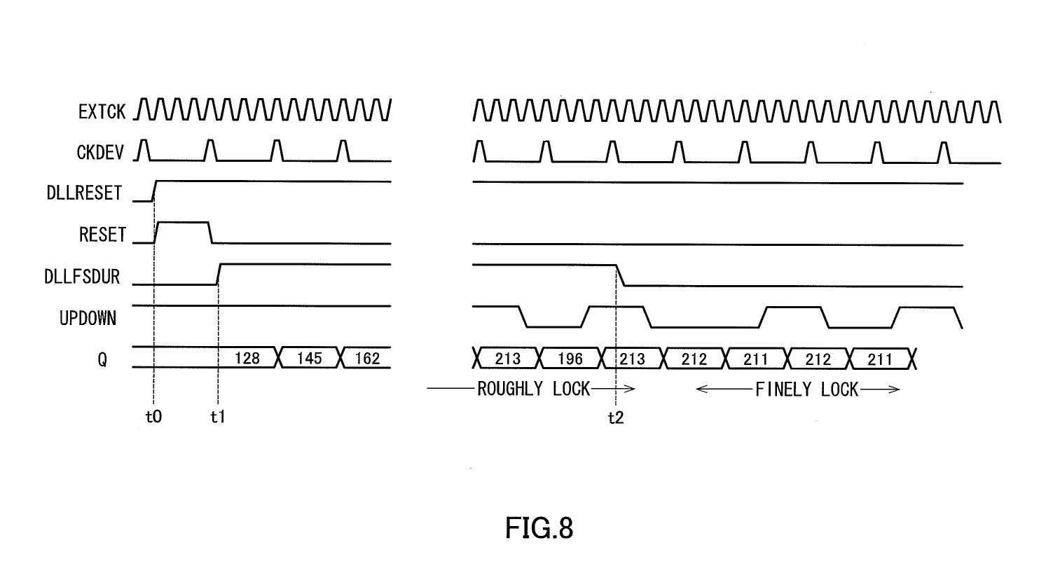

FIG. 8 is a timing chart showing an example of the processing operation of the DLL 100. With reference to FIG. 8, the processing operation of the DLL 100 in which the phase of the clock INTCKX coincides with that of the clock EXTCKX will be explained specifically below.

Firstly, when the reset signal DLLRESET inputted from outside goes up, the reset pulse generator 6 sets the reset pulse signal RESET to be high (time t0). When the reset pulse signal RESET becomes high, the unit variable counter 9 sets the number of delay stages Q to be “128” as an initialization.

Then, when the reset pulse generator 6 sets the reset pulse signal RESET to be low, the rough adjustment period generator 7 sets the signal DLLFSDUR to be high in order to perform the rough adjustment (time t1). The phase comparator 5 compares the clock EXTCKX with the clock INTCKX and inputs the comparison result to the unit variable counter 9 as the signal UPDOWN. During the time t1 to t2, the rough adjustment of the number of delay stages Q is performed because the signal DLLFSDUR is high. More specifically, in synchronization with the divided clock CKDEV, the unit variable counter 9 increases the number of delay stages Q by “17” or “1” (“16” as an average) when the signal UPDOWN is high and decreases the number of delay stages Q by “17” or “1” (“16” as an average) when the signal UPDOWN is low. The increase/decrease unit of the number of delay stages Q during the rough adjustment period has already been explained above.

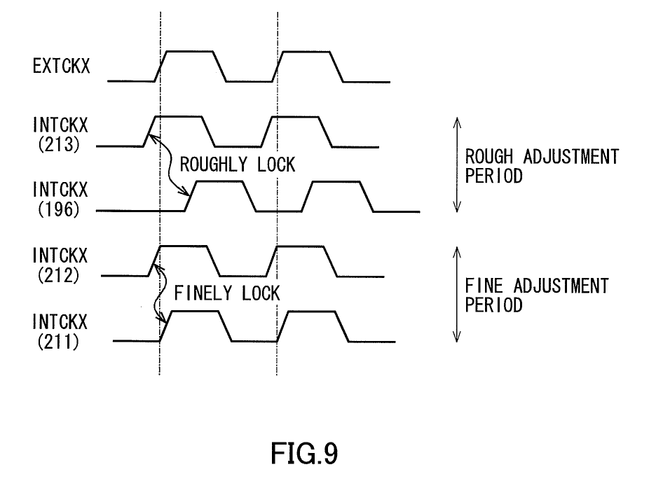

FIG. 9 is a timing chart showing a state where the clock EXTCKX and the clock INTCKX are locked (stabilized). FIG. 8 shows an example where the phase of the clock INTCKX is faster than that of clock EXTCKX when the number of delay stages Q is the initial number of delay stages “128”, and the unit variable counter 9 increases the number of delay stages Q by “17” during the rough adjustment period. As shown in FIG. 9, when the number of delay stages Q becomes “213”, the phase of the clock INTCKX is slower than that of the clock EXTCKX. As a result, the number of delay stages Q decreases by “17”, namely, from “213” to “196”. Therefore, the relationship between the phase of the clock EXTCKX and that of the clock INTCKX is suddenly reversed. As mentioned above, because the number of delay stages Q is roughly adjusted during the rough adjustment period, it is difficult for the phase of the clock INTCKX to coincide with that of the clock EXTCKX precisely, while the phase of the clock INTCKX can be approached to that of the clock EXTCKX in a short time.

Thus, as a result of the rough adjustment, the phase difference between the clock INTCKX and the clock EXTCKX becomes smaller than a delay time corresponding to the number of delay stages of “17” which is the maximum increase/decrease unit.

The rough adjustment period lasts for “8” CKDEV clocks of the unit variable counter 9. The reason therefor is that a number obtained by rounding up a value obtained by dividing the initial number of delay stages (128) by the maximum value (17) of the increase/decrease unit of the unit variable counter 9 is “8” CKDEV clocks. Because this period is a maximum required for roughly lock, this period is set as a rough adjustment period.

After the rough adjustment period, the rough adjustment period generator 7 sets the signal DLLSFDUR to be low in order to perform the fine adjustment (time t2). And then, the unit variable counter 9 sets the increase/decrease unit to be “1” to perform the fine adjustment of the number of delay stages Q of the delay chain circuit 2. In FIG. 8 and FIG. 9, when the number of delay stages Q is “213”, the phase comparator 5 sets the signal UPDOWN to be low because the phase of the clock INTCKX is delayed more than that of the clock EXTCKX. The unit variable counter 9 decreases the number of delay stages Q by “1”, and the clock INTCKX and the clock EXTCKX finally lock when the number of delay stages Q becomes “211” or “212”. Because the increase/decrease unit at the maximum is “17” during the rough adjustment period, the period required for a fine lock by the fine adjustment is “17−1=16” CKDEV clocks.

Thus, as a result of the fine adjustment, the phase difference between the clock INTCKX and the clock EXTCKX is smaller than a delay time corresponding to the one delay stage Q which is the increase/decrease unit during the fine adjustment period.

Therefore, the total period required by when the internal clock INTCK is locked is “8+16=24” CKDEV clocks from a rising time of the reset signal DLLRESET, and in this period, the internal clock INTCK is definitely locked. If the unit variable counter 9 adjusts the delay time Tx of the delay chain circuit 2 with a constant increase/decrease unit of “1” without the rough adjustment period generator 7, the average clock required for the lock is “128” CKDEV clocks. In the present embodiment, the rough adjustment period generator 7 is provided, and the increase/decrease unit of the number of delay stages Q is changed according to the rough adjustment period or the fine adjustment period to adjust the delay time Tx, thereby drastically shortening the period required by when the DLL 100 is locked.

As stated above, in the first embodiment, the number of delay stages Q of the delay chain circuit 2 is set by the unit variable counter 9. Furthermore, the unit variable counter 9 performs the rough adjustment by setting the increase/decrease unit of the number of delay stages Q to be “17” or “1” (“16” as an average) to roughly lock the clock INTCKX, and then the unit variable counter 9 performs the fine adjustment by setting the increase/decrease unit of the number of delay stages Q to be “1” to finely lock the clock INTCKX. Therefore, the phase of the clock INTCKX can surely coincide with that of the clock EXTCKX in a short time.

### Second Embodiment

A second embodiment is a modified example of the first embodiment, where the unit variable counter 9 is modified and the increase/decrease unit during the rough adjustment period is constantly set to be “16”.

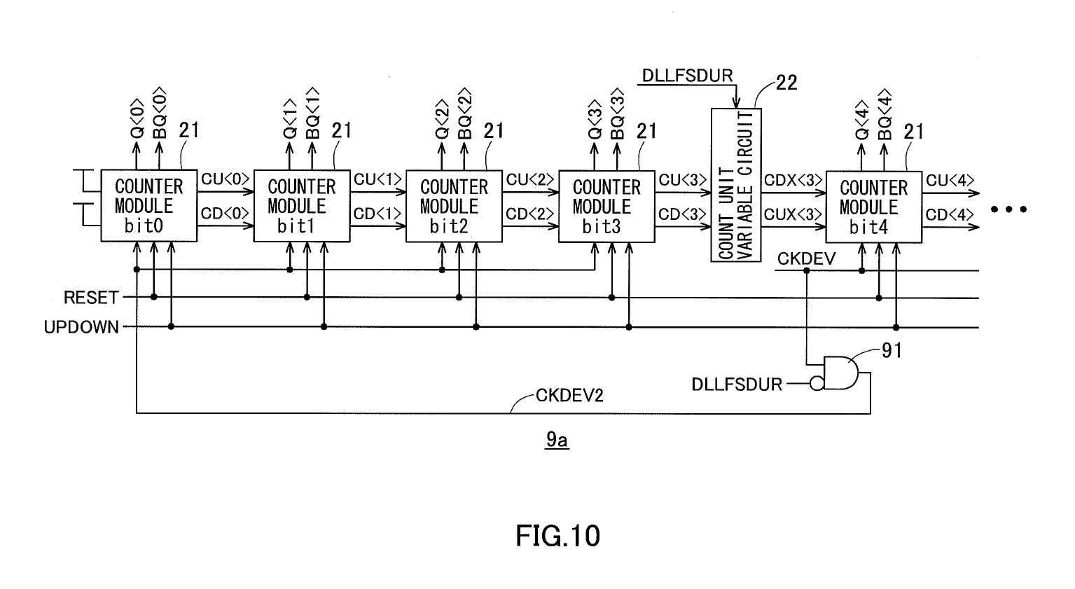

FIG. 10 is a block diagram showing an example of an internal configuration of the unit variable counter 9a. In FIG. 10, components common to those of FIG. 3 have common reference numerals, respectively. Hereinafter, components different from FIG. 3 will be mainly described below.

The unit variable counter 9a of FIG. 10 further has a logic gate circuit 91 in addition to the configuration in FIG. 3. The logic gate circuit 91 generates a divided clock CKDEV2 by performing AND operation between the divided clock CKDEV and an inversed signal of the signal DLLFSDUR. The divided clock CKDEV is inputted to the counter modules 21 at the fifth or upper bits from the lower bit side as well as FIG. 3, while the divided clock CKDEV2 is inputted to the counter modules 21 at from the LSB to the fourth bit.

During the rough adjustment period, the signal DLLFSDUR is high. Therefore, the divided clock CKDEV2 outputted from the logic gate circuit 91 becomes low. As a result, the counter modules 21 at from the LSB to the fourth bit do not perform the count up/down operation. Therefore, only the counter modules 21 at half of the upper bit side, namely, at from the MSB to the fifth bit, perform the count up/down operation in synchronization with the divided clock CKDEV2. Accordingly, the number of delay stages Q during the rough adjustment period is constantly set to be “16”.

During the fine adjustment period, the signal DLLFSDUR is low. Therefore, the logic gate circuit 91 generates the divided signal CKDEV2 having the phase of which is the same as that of the divided signal CKDEV. Accordingly, the number of delay stages Q during the fine adjustment period is constantly set to be “1” as well as the first embodiment.

The present embodiment is the same as the first embodiment except the internal configuration of the unit variable counter 9. In the present embodiment, the period required for the rough lock is “8” CKDEV clocks, which is a value obtained by dividing the initial number of delay stages (128) by the increase/decrease unit (16) and then rounding up the divided value. Furthermore, the period required for finely lock is “16−1=15” CKDEV clocks. Therefore, the total period required by when the internal clock INTCK is locked is “8+15=23” CKDEV clocks from the rising time of the reset signal DLLRESET, and during this period, the internal clock INTCK is definitely locked.

As stated above, in the second embodiment, during the rough adjustment period, the DLL 100 does not provide the counter modules 21 at from the LSB to the fourth bit with a clock and provides only the counter modules 21 at half of the upper bit side with the clock. Therefore, only the counter modules 21 at half of the upper bit side perform the count up/down operation, and it is possible to perform the rough adjustment by constantly setting the increase/decrease unit of the number of delay stages Q to be “16” during the rough adjustment period. Accordingly, the number of the counter modules 21 which operate during the rough adjustment period can be decreased, thereby decreasing consumption power.

Also in FIG. 10, the increase/decrease unit of the number of delay stages during the rough adjustment period can be set to be “2^{k}” which is equal to or more than “2” by changing the number of the counter modules 21 connected in the left side of the count unit varying circuit 22.

### Third Embodiment

A third embodiment is a modified example of the second embodiment, where the increase/decrease unit during the rough adjustment period is an optimum value which is equal to or more than “2”.

When the increase/decrease unit of the unit variable counter 9 during the rough adjustment period is large, a period required by when the internal clock INTCK is roughly locked (hereinafter, period T1) becomes short while a period required by when the internal clock INTCK is finely locked (hereinafter, period T2) becomes long. Contrarily, when the increase/decrease unit is small, the period T1 becomes long while the period T2 is short. Therefore, the present embodiment targets that the increase/decrease unit is set to be an optimum value to further shorten the total period required for the lock (hereinafter, total period T).

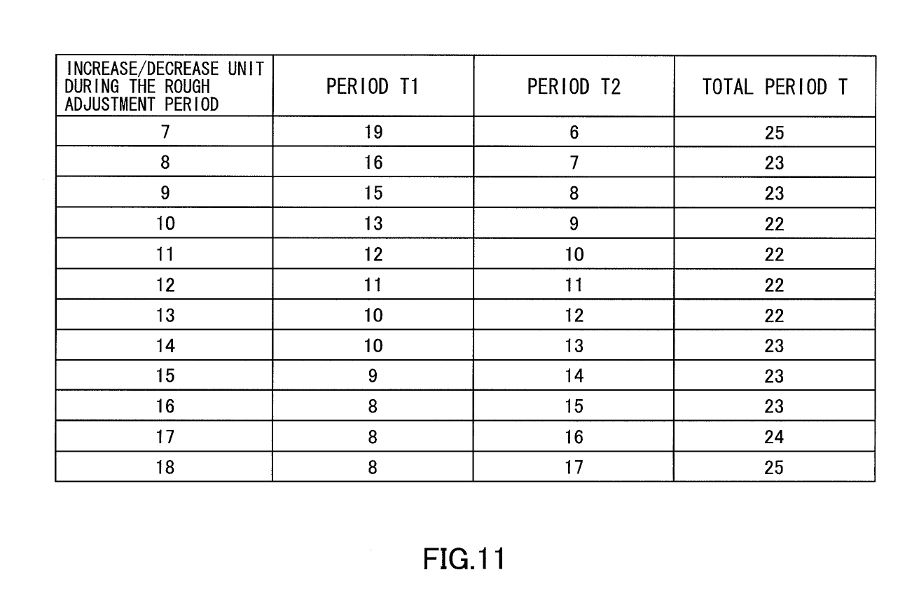

FIG. 11 is a table showing a relationship of the increase/decrease unit in the DLL 100 during the rough adjustment period, the period T1, the period T2 and the total period T. The period T1 is an integer obtained by dividing the initial number of delay stages (128) by the increase/decrease unit of the unit variable counter 9 and then rounding up the divided value. The period T2 is a value obtained by subtracting “1” from the increase/decrease unit. The total period T is a sum of the period T1 and the period T2. Because it is obvious that the total period T is not the shortest when the increase/decrease unit is equal to or more than “6” and is equal to or less than “19”, FIG. 11 shows only the case where the increase/decrease unit is “7” to “18”.

As shown in FIG. 11, the optimum increase/decrease unit is “10” to “13” where the total period T becomes the shortest which is “22” CKDEV clocks. Therefore, by setting the increase/decrease unit of the unit variable counter 9 during the rough adjustment period to be one of “10” to “13”, the internal clock INTCK can be locked in the total period of “22” CKDEV clocks, which is shorter than the total period of “24” CKDEV clocks in the first embodiment and than the total period of “23” CKDEV clocks in the second embodiment.

A period when the signal DLLFSDUR is high is set to be equal to the period T1. For example, when the increase/decrease unit is “10”, the signal DLLFSDUR is high for “13” CKDEV clocks.

The other processing operation is the same as the second embodiment.

In general, assuming that m is the initial number of delay stages and x is the increase/decrease unit during the rough adjustment period, the period T1 is an integer obtained by rounding up a value after a decimal point of m/x, and the period T2 is “x−1”. According to the initial number of delay stages m, by calculating an integer x minimizing the sum of the period T1 and the period T2, the increase/decrease unit of the unit variable counter 9 during the rough adjustment period can be set to be x. Furthermore, the period when the signal DLLFSDUR is high can be set to be the period T1.

The x minimizing the sum of the period T1 and the period T2 can be calculated by preparing the table such as FIG. 11 or can be calculated as explained below. Assuming that the period T1 and x can be non-integers, the total period T is approximated by the following equation (3).

T=m/x+x−1 (3)

Because x is a positive number, x minimizing the equation (3) is √m. Therefore, the integer x minimizing the total period T is the number of stages approximate to square root of the initial number of delay stages m.

When a plurality of x can be obtained by above-mentioned manner, it is possible to select one x capable of configuring the unit variable counter 9 in the simplified way. When the circuit volume of the unit variable counter 9 having the increase/decrease unit of x becomes large, “2^{k}” (here, k is an integer equal to or more than “1”) near x can be used as the increase/decrease unit, instead of the calculated x. Even in this case, the simplified circuit shown in FIG. 10 can implement the unit variable counter 9 without increasing the total period T drastically.

As stated above, in the third embodiment, because the increase/decrease unit of the unit variable counter 9 during the rough adjustment period is set to be the optimum value, the phase of the clock INTCKX can coincide with that of the clock EXTCKX in shorter period by the DLL 100.

### Fourth Embodiment

In a fourth embodiment, the DLL is implemented by more simplified circuit.

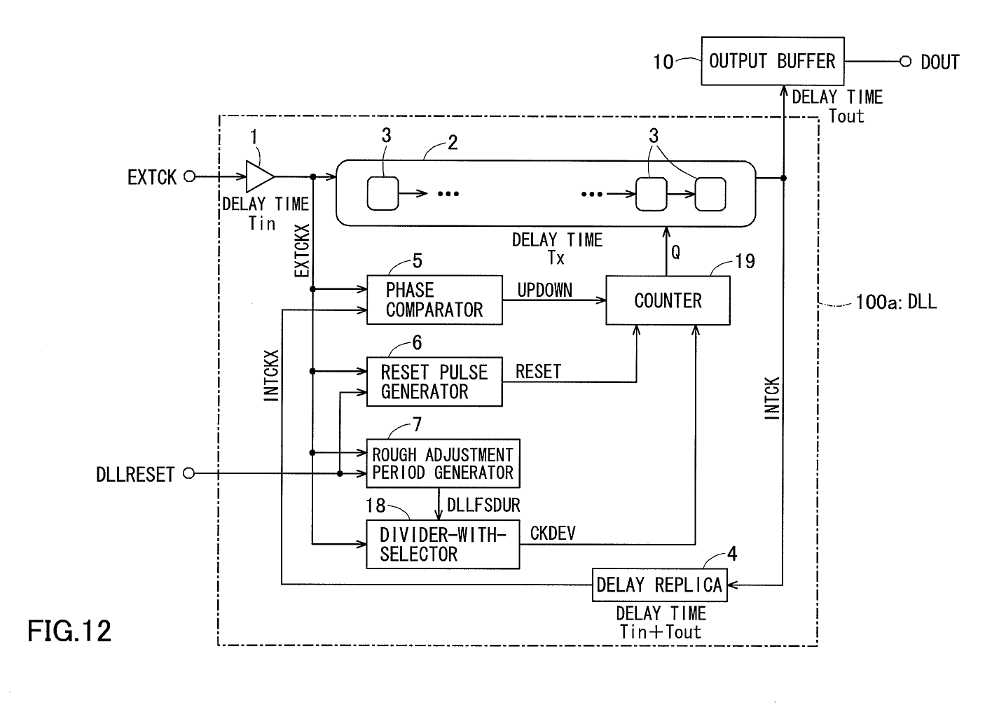

FIG. 12 is a block diagram showing a schematic configuration of a DLL circuit 100a according to the fourth embodiment of the present invention. In FIG. 12, components common to those of FIG. 1 have common reference numerals, respectively. Hereinafter, components different from FIG. 1 will be mainly described. The DLL 100a has a divider-with-selector 18 instead of the divider 8 and has a counter (delay controller) 19 instead of the unit variable counter 9. The signal DLLFSDUR generated by the rough adjustment period generator 7 is provided to the divider-with-selector 18.

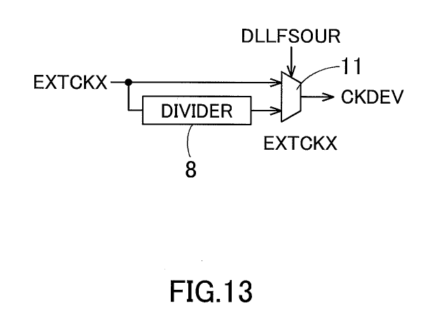

FIG. 13 is a block diagram showing an example of an internal configuration of the divider-with-selector 18. As shown in FIG. 13, the divider-with-selector 18 has the divider 8 and a multiplexer 11. The divider 8 generates a divided clock whose frequency is ¼ of that of the external clock EXTCK as well as the first embodiment. The multiplexer 11 selects the clock EXTCKX, which is not divided when the signal DLLFSDUR is high, namely, during the rough adjustment period and selects the divided clock divided by the divider 8 when the signal DLLFSDUR is low, namely, during the fine adjustment period. Furthermore, the multiplexer 11 provides the counter 19 with the selected clock CKDEV.

The counter 19 increases or decreases the number of delay stages Q by the increase/decrease unit of “1” in synchronization with the clock CKDEV regardless of the rough adjustment period or the fine adjustment period. However, the counter 19 increases or decreases the number of delay stages Q by “1” in synchronization with the non-divided clock CKDEV (first cycle) during the rough adjustment period, while in synchronization with divided clock CKDEV (second cycle) during the fine adjustment period. Therefore, the number of delay stages Q during the rough adjustment period varies four times faster than that during the fine adjustment period.

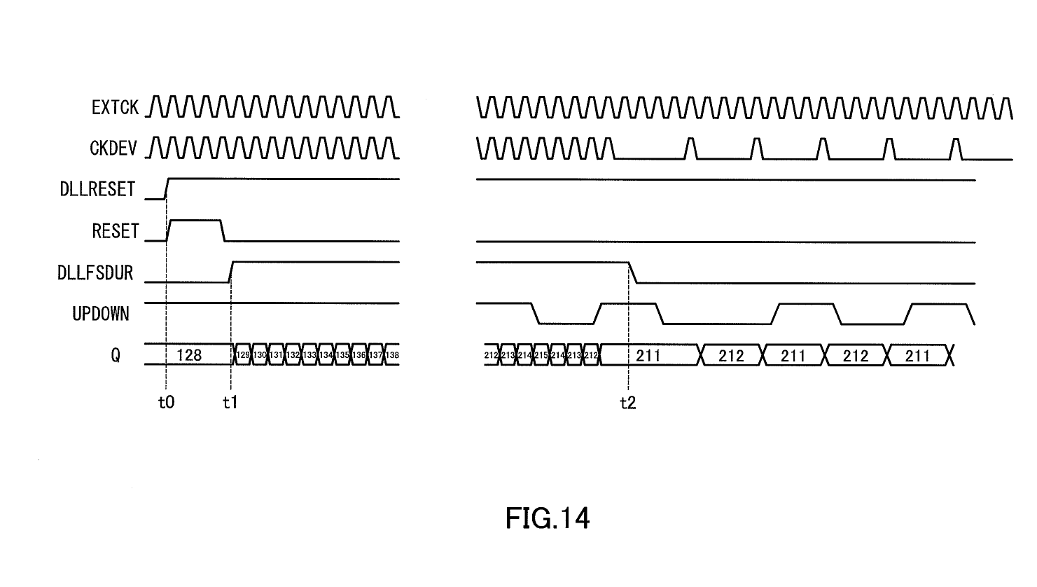

FIG. 14 is a timing chart showing an example of the processing operation of the DLL 100a. With reference to FIG. 14, the processing operation of the DLL 100a for a phase of the clock INTCKX to coincide with that of the clock EXTCKX will be specifically explained below.

Firstly, when the reset signal DLLRESET provided from outside rises, the reset pulse generator 6 sets the reset pulse signal RESET to be high (time t0). When the reset pulse signal RESET becomes high, the counter 19 sets the number of delay stages Q to be an initial number of delay stages “128” as an initialization.

Then, when the reset pulse generator 6 sets the reset pulse signal RESET to be low, the rough adjustment period generator 7 sets the signal DLLFSDUR to be high in order to perform the rough adjustment (time t1). The phase comparator 5 compares the clock EXTCKX with the clock INTCKX and provides the comparison result to the counter 19 as a signal UPDOWN. During the time from t1 to t2, the rough adjustment of the number of delay stages Q is performed because the signal DLLFSDUR is high. More specifically, in synchronization with the non-divided clock CKDEV, the counter 19 increases the number of delay stages Q by “1” when the signal UPDOWN is high and decreases the number of delay stages Q by “1” when the signal UPDOWN is low.

As mentioned above, the feedback loop of the DLL 100a needs more than “3” cycles of the external clock EXTCK. Therefore, even if the increase/decrease unit of the number of delay stages Q is “1”, the signal UPDOWN outputted by the phase comparator 5 varies with a cycle longer than “3” cycles of the external clock EXTCK. Accordingly, the DLL 100a of FIG. 12 performs an operation which is equivalent to the rough adjustment of the number of delay stages Q in accordance with the cycle with which the output of the phase comparator 5 varies.

Then the rough adjustment period generator 7 sets the signal DLLFSDUR to be low in order to perform the fine adjustment (time t2). Because of this, the counter 19 increases or decreases the number of delay stages Q by “1” in synchronization with the divided clock CKDEV. Because the frequency of the divided clock CKDEV is ¼ of that of the external clock EXTCK, the delay time of the clock INTCKX can fully follow the number of delay stages Q. Therefore, the DLL 100a can perform the fine adjustment where the increase/decrease unit is “1”.

The rough adjustment period can arbitrarily be set from outside. Or the rough adjustment period can be set to be the maximum period required for roughly lock, which is a value obtained by rounding up a value obtained by dividing the initial number of delay stages (128) by practically following delay stage (3), namely, “43” cycles of the external clock EXTCK.

Thus, the counter 19 performs the operation similar to a normal up/down counter. Therefore, the counter 19 can be implemented more simply than the unit variable counter 9 of FIG. 3 and FIG. 10, thereby shrinking the circuit scale.

FIG. 14 is a timing chart showing an example where the number of delay stages Q locks at “211” or “212” as well as FIG. 8. During the rough adjustment period, the rough adjustment is performed by increasing the number of delay stages Q by “1” in synchronization with the non-divided clock CKDEV firstly. As mentioned above, though the number of delay stages Q varies by “1”, a determination of the count-up or count-down is performed at an interval longer than “3” cycles of the external clock EXTCK. As a result, the rough adjustment is performed.

When the number of delay stages becomes “212”, the phase of the clock INTCKX is delayed more than that of the clock EXTCKX. However, because the delay time of the clock INTCKX cannot follow the number of delay stages Q, the number of delay stages Q increases up to “215”. Then, in order to forward the phase of the clock INTCKX, the counter 19 decreases the number of delay stages Q by “1”. When the signal DLLFSDUR becomes low, the counter 19 performs the fine adjustment by increasing/decreasing the number of delay stages Q in synchronization with the divided clock CKDEV. Because the cycle of the divided clock is long, the determination of the count-up or count-down is performed by “1” cycle of this clock, thereby performing the fine adjustment. By performing such a fine adjustment, the number of delay stages Q is finally locked at “211” or “212”.

As stated above, in the fourth embodiment, because the frequency inputted to the counter 19 is switched according to the rough adjustment period or the fine adjustment period, the increase/decrease unit is unnecessary to be switched according to the rough adjustment period or the fine adjustment period. Therefore, the DLL 100a can be implemented by more simplified circuit configuration.

Each of the embodiments described above shows one example in which the phase of the clock EXTCKX (first signal) coincides with that of the clock INTCKX (third signal) and the internal clock INTCK (second signal) having the phase faster than the phase of the external clock EXTCK by the delay time Tout of the output buffer 10 is generated. However, applications of the DLL are not limited to these, and the DLL is applicable to other purposes. That is, the present invention can be widely applicable to circuit (DLL) which performs control so that the phase of the third signal coincides with that of the first signal when generating the second signal by delaying the first signal and generating the third signal by further delaying the second signal.

More specifically, the DLL according to the present invention has at least the delay chain circuit 2, the delay replica 4, the phase comparator 5, the rough adjustment period generator 7, and the unit variable counter 9. The DLL can have the counter 19 instead of the unit variable counter 9. With these configurations, the phase of any kind of the first signal can coincide with that of a third signal obtained by delaying the first signal by a predetermined time.

The DLL described above cannot be only integrated in a memory or a memory controller, but is applicable to various devices which have to perform phase compensation between different signals.

The internal configuration of the unit variable counter shown in FIG. 3 to FIG. 5 and FIG. 10 is only an example, and various modifications can be conceivable. For example, the increase/decrease unit (first unit) of the number of delay stages Q during the fine adjustment period of the first to the third embodiments or the increase/decrease unit (second unit) of the number of delay stages Q of the fourth embodiment is not necessarily “1”. Furthermore, the DLL according to the present invention can be formed on a semiconductor substrate using MOS transistors or bipolar transistors or the like, or can be implemented on the printed circuit board using discrete parts.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A delay-locked loop circuit comprising:
an adjustment period setting module configured to set a rough adjustment period comprising a number of delay stages and a fine adjustment period comprising a substantially smaller number of delay stages;
a delay time adjustment module configured to increase or decrease a number of delay stages by a first amount or by a second amount based on a delay stages setting value in order to generate a second signal by delaying a first signal;
a delay module configured to generate a third signal by delaying the second signal by a predetermined time;
a phase comparator configured to detect a phase difference between the first signal and the third signal; and
a delay controller configured to generate the delay stages setting value based on the phase difference in order to increase or decrease the number of delay stages by the first amount when the rough adjustment period is set and in order to increase or decrease the number of delay stages by the second amount when the fine adjustment period is set.

2. The circuit of claim 1, wherein the delay controller comprises:
a first counter comprising a plurality of counter modules configured to set a lower side of a bit string indicative of the number of delay stages;
a second counter comprising a plurality of counter modules configured to set a upper side of the bit string indicative of the number of delay stages; and
a count unit adjuster between the first and second counters, which is configured to set a carry value from the first counter to the second counter during the rough adjustment period and the fine adjustment period.

3. The circuit of claim 2, wherein the count unit adjuster is configured to set the carry value to be a predetermined value during the rough adjustment period, and to set the carry value to be a value of a carry of the first counter during the fine adjustment period.

4. The circuit of claim 2, wherein the delay controller comprises a clock controller configured to stop a count operation of the first counter and to control the second counter to count during the rough adjustment period, and to control the first and second counters to count during the fine adjustment period.

5. The circuit of claim 1, wherein the first amount is larger than the second amount, and
the delay controller is configured to roughly adjust by generating the delay stages setting value in order to set the phase difference between the first signal and the third signal to be smaller than a period corresponding to the first amount when the rough adjustment period is set, and to finely adjust by generating the delay stages setting value in order to set the phase difference between the first signal and the third signal to be smaller than a time corresponding to the second amount when the fine adjustment period is set.

6. The circuit of claim 5, further comprising a divider configured to generate a divided signal by frequency-dividing the first signal,
wherein the delay controller is configured to generate the delay stages setting value in synchronization with the divided signal, and
the adjustment period setting module is configured to switch from the rough adjustment period to the fine adjustment period after a substantially maximum period for the rough adjustment has lapsed.

7. The circuit of the claim 5, wherein the delay time controller is configured to set the first amount in such a manner that a sum of a period for the rough adjustment and a period for the fine adjustment becomes a substantially minimum according to a substantially maximum number of delay stages; and
the adjustment period setting module is configured to switch from the rough adjustment period to the fine adjustment period when the sum of the period for the rough adjustment and the period for the fine adjustment becomes substantially the minimum.

8. The circuit of claim 1, wherein the first amount is “2^{k}” where k is a positive integer.

9. The circuit of claim 8, wherein the first amount “2^{k}” is the substantial approximate to a square root of half of the maximum value of the number of delay stages.

10. The circuit of claim 1 further comprising an input buffer configured to receive a signal from outside in order to generate the first signal;
wherein the delay module is configured to generate the third signal by delaying the second signal by the predetermined time in consideration of a time for the input buffer in order to generate the first signal and of a delay time of an output buffer for outputting data in a memory in synchronization with the second signal.

11. The circuit of claim 10, wherein the delay time adjustment module is configured to generate the second signal comprising a phase faster than a phase of the signal from outside by the delay time of the output buffer.

12. The circuit of claim 1 further comprising a reset pulse signal generator configured to generate a reset pulse signal in synchronization with a reset signal;
wherein the delay controller is configured to set the number of delay stages to be half of the substantially maximal number of delay stages when the reset pulse signal is generated, and
the adjustment period setting module sets the rough adjustment period when the reset pulse signal is generated.

13. A delay-locked loop circuit comprising:
an adjustment period setting module configured to set a rough adjustment period comprising a number of delay stages and a fine adjustment period comprising a substantially smaller number of delay stages;
a delay time adjustment module configured to generate a second signal by delaying a first signal based on a delay stages setting value;
a delay module configured to generate a third signal by delaying a second signal by a predetermined time;
a phase comparator configured to detect a phase difference between the first signal and the third signal; and
a delay controller configured to update the delay stages setting value with a first cycle when the rough adjustment period is set and with a second cycle which is longer than the first cycle when the fine adjustment period is set.

14. The circuit of claim 13 further comprising:
a divider configured to generate a divided signal by frequency-dividing the first signal; and
a multiplexer configured to output the first signal when the rough adjustment period is set and to output the divided signal when the fine adjustment period is set;
wherein the delay controller is configured to update the delay stages setting value by setting the cycle of the first signal as the first cycle when the rough adjustment period is set and by setting the cycle of the divided signal as the second cycle when the fine adjustment period is set.

15. The circuit of claim 13 further comprising an input buffer configured to receive a signal from outside in order to generate the first signal;
wherein the delay module is configured to generate the third signal by delaying the second signal by the predetermined time in consideration of a time for the input buffer to generate the first signal and of a delay time of an output buffer for outputting data in a memory in synchronization with the second signal.

16. The circuit of claim 13, wherein the delay time adjustment module is configured to generate the second signal comprising the phase faster than the phase of the signal from outside by the delay time of the output buffer.

17. The circuit of claim 13 further comprising a reset pulse signal generator configured to generate a reset pulse signal in synchronization with a reset signal;
wherein the delay controller is configured to set the number of delay stages to be half of the maximum of the number of delay stages when the reset pulse signal is generated, and
the adjustment period setting module is configured to set the rough adjustment period when the reset pulse signal is generated.

18. A method for synchronization by delay-locked loop comprising:
setting a rough adjustment period comprising a number of delay stages and a fine adjustment period comprising a substantially smaller number of delay stages;
increasing or decreasing a number of delay stages by a first amount or by a second amount based on a delay stages setting value;
generating a second signal by delaying a first signal;
generating a third signal by delaying the second signal for a predetermined time;
detecting a phase difference between the first signal and the third signal; and
generating the delay stages setting value based on the phase difference in order to increase or decrease the number of delay stages by the first amount when the rough adjustment period is set and to increase or decrease the number of delay stages by the second amount when the fine adjustment period is set.

19. The method of claim 18, wherein the first amount is larger than the second amount, and
a rough adjustment is executed by generating the delay stages setting value in order to set the phase difference between the first signal and the third signal to be smaller than a period corresponding to the first amount when the rough adjustment period is set, and a fine adjustment is executed by generating the delay stages setting value in order to set the phase difference between the first signal and the third signal to be smaller than a time corresponding to the second amount when the fine adjustment period is set, upon generating the delay stages setting value.

20. The method of claim 18, further comprising receiving a signal from outside in order to generate the first signal by an input buffer;
wherein a third signal is generated by delaying the second signal by the predetermined time in consideration of a time for the input buffer to generate the first signal and a delay time of an output buffer for outputting data in a memory in synchronization with the second signal, and
a second signal comprising the phase faster than the phase of the signal from outside by the delay time of the output buffer is generated.
